(19) United States
(12) Patent Application Publication
(10) Pub. No.: US 2025/0191953 A1
(43) Pub. Date: Jun. 12, 2025

(54) ENCAPSULATED COMPRESSION WASHER FOR BONDING CERAMIC PLATE AND METAL BASEPLATE OF ELECTROSTATIC CHUCKS

(71) Applicant: LAM RESEARCH CORPORATION, Fremont, CA (US)

(72) Inventor: Eric A. PAPE, Santa Cruz, CA (US)

(21) Appl. No.: 18/842,516

(22) PCT Filed: Mar. 2, 2023
(86) PCT No.: PCT/US2023/014374

§ 371 Date: Aug. 29, 2024

Related U.S. Application Data
(60) Provisional application No. 63/317,822, filed on Mar. 8, 2022.

(51) Int. Cl. H01L 21/683

(52) U.S. Cl. CPC H01L 21/6833

(57) ABSTRACT

An electrostatic chuck for a substrate processing system includes a baseplate, a ceramic plate, and a bond layer. The baseplate includes a metallic material, a sidewall and upper and lower surfaces of the baseplate defining a plenum. The baseplate further includes an inlet in fluid communication with the plenum and a first plurality of through holes extending from the upper surface to the plenum. The ceramic plate includes a second plurality of through holes extending between upper and lower surfaces of the ceramic plate. The bond layer bonds the baseplate and the ceramic plate. The bond layer includes a plurality washers. Each washer includes a core comprising a third material and a coating of a fourth material surrounding the core. The washers and the bond layer are of the same height. Inner diameters of the washers are aligned with diameters of the first and second plurality of through holes.

### CROSS-REFERENCE TO RELATED APPLICATIONS

This application claims the benefit of U.S. Provisional Application No. 63/317,822, filed on Mar. 8, 2022. The entire disclosure of the application referenced above is incorporated herein by reference.

### FIELD

The present disclosure relates generally to substrate processing systems and more particularly to encapsulated compression washers for bonding ceramic plate and metal baseplate of electrostatic chucks.

### BACKGROUND

The background description provided here is for the purpose of generally presenting the context of the disclosure. Work of the presently named inventor, to the extent it is described in this background section, as well as aspects of the description that may not otherwise qualify as prior art at the time of filing, are neither expressly nor impliedly admitted as prior art against the present disclosure.

A substrate processing system comprises processing chambers to perform deposition, etching, and other treatments of substrates such as semiconductor wafers. Examples of processes that may be performed on a substrate comprise plasma enhanced chemical vapor deposition (PECVD), chemically enhanced plasma vapor deposition (CEPVD), sputtering physical vapor deposition (PVD), atomic layer deposition (ALD), and plasma enhanced ALD (PEALD). Additional examples of processes that may be performed on a substrate comprise etching (e.g., chemical etching, plasma etching, reactive ion etching, etc.) and cleaning processes.

During processing, a substrate is arranged on a substrate support assembly such as a pedestal or an electrostatic chuck (ESC) arranged in a processing chamber of the substrate processing system. A robot typically transfers substrates from one processing chamber to another in a sequence in which the substrates are to be processed. During deposition, gas mixtures comprising one or more precursors are introduced into the processing chamber, and plasma is struck to activate chemical reactions. During etching, gas mixtures comprising etch gases are introduced into the processing chamber, and plasma is struck to activate chemical reactions. The processing chambers are periodically cleaned by supplying a cleaning gas into the processing chamber and striking plasma.

### SUMMARY

An electrostatic chuck for a substrate processing system comprises a baseplate, a ceramic plate, and a bond layer. The baseplate of the electrostatic chuck comprises a metallic material, a sidewall and upper and lower surfaces of the baseplate defining a plenum. The baseplate further comprises an inlet in fluid communication with the plenum and a first plurality of through holes extending from the upper surface to the plenum. The ceramic plate of the electrostatic chuck comprises a second plurality of through holes extending between upper and lower surfaces of the ceramic plate. The bond layer bonds the baseplate and the ceramic plate. The bond layer comprises a plurality washers. Each washer comprises a core comprising a third material and a coating of a fourth material surrounding the core. The washers and the bond layer are of the same height. Inner diameters of the washers are aligned with diameters of the first and second plurality of through holes.

In additional features, the core and the coating are annular and coaxial.

In additional features, the inlet, the plenum, the inner diameters of the washers, and the first and second plurality of through holes are in fluid communication with each other.

In additional feature, the bond layer comprises the third material.

In additional feature, the third material comprises silicone, urethane, or flexible epoxy.

In additional feature, the fourth material comprises polytetrafluoroethylene (PTFE) or perfluoroalkoxy alkanes (PFA).

In additional features, the coating comprises a first layer of the fourth material disposed on an inner diameter of the core and a second layer of the fourth material disposed on an outer diameter of the core.

In additional feature, a sum of thicknesses of the first and second layers is less than or equal to a thickness of the core.

In additional feature, a sum of thicknesses of the first and second layers is greater than or equal to a thickness of the core.

In additional features, thicknesses of the first and second layers are different.

In additional feature, a diameter of the washers is 2-20 mm.

In additional feature, a thickness of the washers is 2-10 mils.

In additional features, the core comprises 30-90% of a thickness of the washer, and the coating comprises 70-10% of the thickness of the washer.

In additional features, the electrostatic chuck further comprises an O-ring arranged around the bond layer. The O-ring comprises a second core comprising the third material, and a second coating comprising the fourth material surrounding the second core.

In additional features, an inner diameter of the O-ring is 300 mm, and a cross-sectional diameter of the O-ring is 100-150 mils.

In additional features, the ceramic plate comprises one or more passages. One of the passages connects one of the second plurality of through holes at the lower surface of the ceramic plate to at least two of the second plurality of through holes at the upper surface of the ceramic plate.

In still other features, and electrostatic chuck for a substrate processing system comprises a baseplate, a ceramic plate, and a bond layer. The baseplate comprises a sidewall and upper and lower surfaces of the baseplate defining a plenum, an inlet in fluid communication with the plenum, and a first plurality of through holes extending from the upper surface to the plenum. The ceramic plate comprises a second plurality of through holes extending through the ceramic plate. The bond layer bonds the baseplate and the ceramic plate. The bond layer comprises a plurality washers. Each washer comprises a core and a coating disposed on the core. Inner diameters of the washers are aligned with diameters of the first and second plurality of through holes.

In additional features, the core and the coating are annular and coaxial.

In additional features, the baseplate comprises a metallic material. The bond

layer and the core comprise a third material. The coating comprises a polymeric material.

In additional features, the baseplate comprises a metallic material. The bond layer comprises silicone. The core comprises silicone, urethane, or flexible epoxy. The coating comprises polytetrafluoroethylene (PTFE) or perfluoroalkoxy alkanes (PFA).

In additional features, the washers and the bond layer are of the same height.

In additional feature, the coating partially surrounds of the core.

In additional feature, the coating fully surrounds of the core.

In additional features, the inlet, the plenum, the inner diameters of the washers, and the first and second plurality of through holes are in fluid communication with each other.

In additional features, the coating comprises a first layer disposed on an inner diameter of the core and a second layer disposed on an outer diameter of the core.

In additional feature, a sum of thicknesses of the first and second layers is less than or equal to a thickness of the core.

In additional feature, a sum of thicknesses of the first and second layers is greater than or equal to a thickness of the core.

In additional features, thicknesses of the first and second layers are different.

In additional feature, a diameter of the washers is 2-20 mm.

In additional feature, a thickness of the washers is 2-10 mils.

In additional features, the core comprises 30-90% of a thickness of the washer, and the coating comprises 70-10% of the thickness of the washer.

In additional features, the electrostatic chuck further comprises an O-ring arranged around the bond layer. The O-ring comprises a second core comprising the same material as the core of the washers, and a second coating surrounding the second core and comprising the same material as the coating of the washers. In additional features, an inner diameter of the O-ring is 300 mm, and a cross-sectional diameter of the O-ring is 100-150 mils.

In additional features, the ceramic plate comprises one or more passages and. One of the passages connects one of the second plurality of through holes at the lower surface of the ceramic plate to at least two of the second plurality of through holes at the upper surface of the ceramic plate.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIGS. 1A and 1B show examples of substrate processing systems comprising an electrostatic chuck (ESC);

FIG. 2 shows a simplified cross-sectional view of components of the ESC comprising washers in a bond layer used to bond a baseplate and a ceramic plate of the ESC according to the present disclosure;

FIG. 3 shows a transverse section of a washer before curing the bond layer;

FIG. 4 shows a plan view of the baseplate comprising through holes and the washers of FIG. 3 arranged around the through holes on the baseplate before curing the bond layer;

FIG. 5 shows a cross-sectional view of the ESC after the bond layer comprising the washers is cured and the baseplate and a ceramic plate of the ESC are bonded by the cured bond layer;

FIG. 6 shows a transverse section of the washer after the bond layer is cured;

FIG. 7 shows a plan view of the through holes and the washers around the through holes on the baseplate after the bond layer is cured;

FIG. 8 shows a cross-sectional view of the ESC of FIG. 5 with the addition of an O-ring disposed around the cured bond layer; and

FIGS. 9 and 10 show examples of cross-sectional views of an ESC with a ceramic plate comprising plenums instead of orthogonal through holes.

In the drawings, reference numbers may be reused to identify similar and/or identical elements.

### DETAILED DESCRIPTION

An electrostatic chuck (ESC) comprises a ceramic plate bonded to a metallic baseplate using a bond layer. A plurality of holes are bored through the baseplate and the ceramic plate before bonding the ceramic plate to the baseplate. The holes are used to supply a gas (e.g., helium) to control temperature of a substrate during processing. During manufacturing, the bond layer is formed by disposing liquid silicone over the baseplate and curing the liquid silicone while compressing the ceramic plate and the baseplate. To prevent the liquid silicone from clogging the holes in the baseplate and the ceramic plate, silicone washers are disposed around the holes. On curing, the bond layer comprising the silicone washers bonds the ceramic plate to the baseplate.

While the silicone washers prevent the liquid silicone from clogging the holes, the silicone washers tend to degrade and fail over time after repeated substrate processing and chamber cleaning. The silicone washers fail due to high process temperatures, temperature cycling, and exposure to reactive plasma species used in substrate processing and chamber cleaning. Specifically, degraded material and uncured plasticizers from the silicone washers leak into the holes and clog the holes. Further, uncured plasticizers from surrounding bonding material diffuse through the silicone washers and leak into the holes, which further clogs the holes. The holes clog due to various other reasons. For example, low gas flow during wafer-less auto-clean (WAC) can result in arcing, light-up (i.e., plasma formation), and ultimately bond erosion and degradation of the bond layer. The clogged holes not only disrupt the flow of gas through the holes but also impair the bonding between the ceramic plate and the baseplate. The impaired bonding eventually causes the ESC to fail.

The present disclosure provides washers comprising an elastic material used as a core material that is coated with a polymeric coating. The elastic core material has mechanical properties to withstand the compressive forces between the baseplate and the ceramic plate during the manufacture of the ESC. Additionally, the core material has thermodynamic properties to withstand high process temperatures. Furthermore, the polymeric coating does not erode due to due to high process temperatures, temperature cycling, and exposure to reactive plasma species. The polymeric coating acts as a diffusive barrier to plasma or other reactive species, and also acts as a diffusive barrier to the core's plasticizers and/or uncured material. As a result, not only the holes remain unclogged, but the bonding between the ceramic plate and the baseplate is also not impaired after several thousand hours of use of the ESC. These and other features of the present disclosure are described below in further detail.

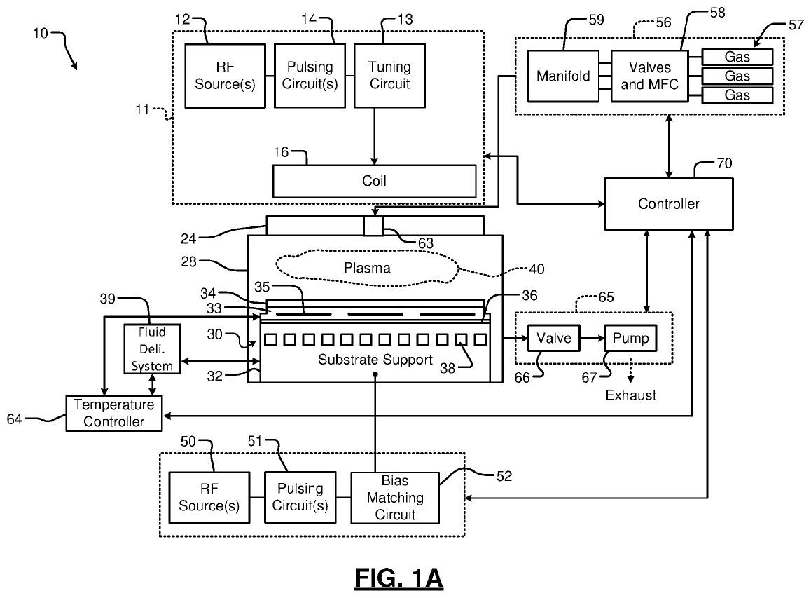

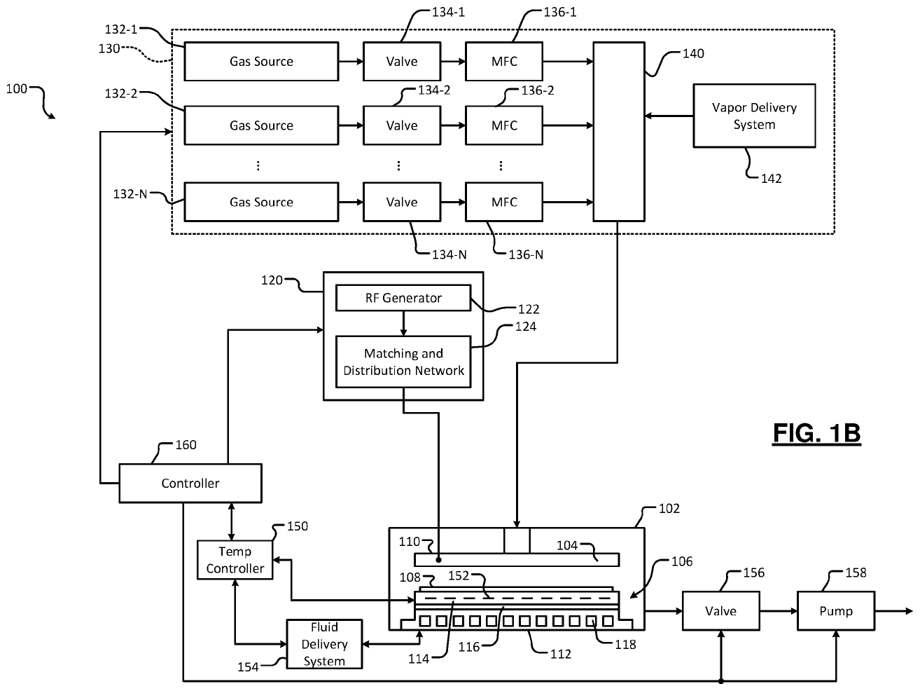

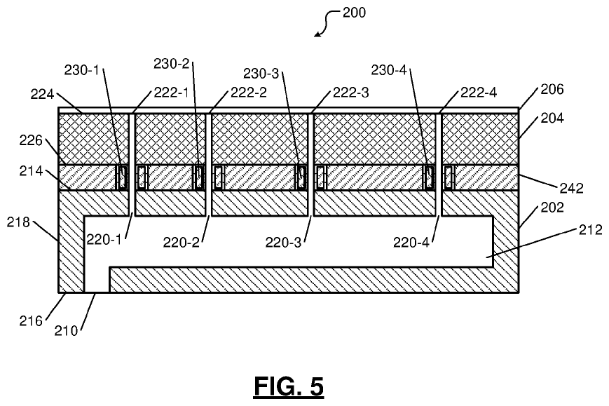

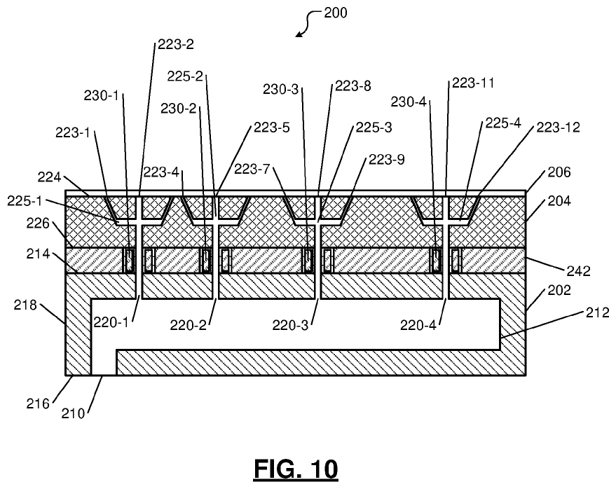

The present disclosure is organized as follows. Initially, examples of substrate processing systems in which ESCs manufactured according to the present disclosure can be used are shown and described with reference to FIGS. 1A and 1B. A method of manufacturing ESCs using coated washers and structural details of the coated washers are shown and described with reference to FIGS. 2-4. An ESC manufactured using the coated washers is shown and described with reference to FIGS. 5-8. FIGS. 2-4 show elements of the ESC before curing the bond layer. FIGS. 5-8 show elements of the ESC after the bond layer is cured. FIGS. 9 and 10 show examples of a ceramic plate comprising plenums instead of orthogonal through holes.

FIG. 1A shows an example of a substrate processing system 10 that uses inductively coupled plasma to etch substrates such as semiconductor wafers according to the present disclosure. The substrate processing system 10 comprises a coil driving circuit 11. In some examples, the coil driving circuit 11 comprises an RF source 12, a pulsing circuit 14, and a tuning circuit (i.e., matching circuit) 13. The pulsing circuit 14 controls a transformer coupled plasma (TCP) envelope of an RF signal generated by the RF source 12 and varies a duty cycle of TCP envelope between 1% and 99% during operation. The pulsing circuit 14 and the RF source 12 can be combined or separate.

The tuning circuit 13 may be directly connected to an inductive coil 16. While the substrate processing system 10 uses a single coil, some substrate processing systems may use a plurality of coils (e.g., inner and outer coils). The tuning circuit 13 tunes an output of the RF source 12 to a desired frequency and/or a desired phase, and matches an impedance of the inductive coil 16.

A dielectric window 24 is arranged along a top side of a processing chamber 28. The processing chamber 28 comprises a substrate support (or pedestal) 30 to support a substrate 34. The substrate support 30 can be manufactured according to the present disclosure as shown and described below in further detail with reference to FIGS. 2-8. Briefly, the substrate support 30 may comprise an electrostatic chuck (ESC), or a mechanical chuck or other type of chuck. The substrate support 30 comprises a baseplate 32. The baseplate 32 comprises a metallic material (e.g., aluminum or an alloy). A ceramic plate 33 is arranged on a top surface of the baseplate 32. A thermal resistance layer (also called a bond layer) 36 is arranged between the ceramic plate 33 and the baseplate 32 to bond the ceramic plate 33 to the baseplate 32 as described below in detail with reference to FIGS. 2-8. The substrate 34 is arranged on the ceramic plate 33 during processing.

A heater array 35 comprising a plurality of heaters is arranged in the ceramic plate 33 to heat the substrate 34 during processing. For example, the heater array 35 comprises printed resistive traces embedded in the ceramic plate 33. One or more additional heaters called zone heaters or primary heaters (not shown) may be arranged above or below the heater array 35. Additionally, while not shown, one or more temperature sensors may be disposed in the ceramic plate 33.

The baseplate 32 further comprises a cooling system to cool the substrate support 30 and to control the temperature of the substrate 34. The cooling system uses a fluid (e.g., a gas such as helium) supplied by a fluid delivery system 39 to cool the substrate support 30. For example, the cooling system comprises cooling channels 38 disposed in the baseplate 32 through which the fluid from the fluid delivery system 39 is flowed to cool the substrate support 30.

A process gas is supplied to the processing chamber 28, and plasma 40 is generated in the processing chamber 28. The plasma 40 etches an exposed surface of the substrate 34. An RF source 50, a pulsing circuit 51, and a bias matching circuit 52 may be used to bias the substrate support 30 during processing to control ion energy.

A gas delivery system 56 supplies a process gas mixture to the processing chamber 28. The gas delivery system 56 may comprise process and inert gas sources 57, a gas metering system 58 such as valves and mass flow controllers, and a manifold 59. A gas injector 63 may be arranged at a center of the dielectric window 24 and is used to inject gas mixtures from the gas delivery system 56 into the processing chamber 28. Additionally, or alternatively, the gas mixtures may be injected from the side of the processing chamber 28.

A temperature controller 64 may be connected to the heater array 35, the zone

heaters, and the temperature sensors in the ceramic plate 33. The temperature controller 64 may be used to control the heater array 35 and the zone heaters to control a temperature of the substrate support 30 and the substrate 34. The temperature controller 64 may communicate with the fluid delivery system 39 to control fluid flow through the cooling system 38 to cool the substrate support 30.

An exhaust system 65 comprises a valve 66 and pump 67 to control pressure in the processing chamber 28 and/or to remove reactants from the processing chamber 28 by purging or evacuation. A controller 70 may be used to control the etching process. The controller 70 controls the components of the substrate processing system 10. The controller 70 monitors system parameters and controls delivery of the gas mixture; striking, maintaining, and extinguishing the plasma; removal of reactants; supply of cooling fluid; and so on. Additionally, the controller 70 may control various aspects of the coil driving circuit 11, the RF source 50, and the bias matching circuit 52, and so on.

FIG. 1B shows another example of a substrate processing system 100 comprising a processing chamber 102 configured to generate capacitively coupled plasma. While the example is described in the context of plasma enhanced chemical vapor deposition (PECVD), the teachings of the present disclosure can be applied to other types of substrate processing such as atomic layer deposition (ALD), plasma enhanced ALD (PEALD), CVD, or other processing comprising etching and cleaning.

The substrate processing system 100 comprises the processing chamber 102 that encloses other components of the substrate processing system 100 and contains RF plasma (if used). The processing chamber 102 comprises an upper electrode 104 and an electrostatic chuck (ESC) 106 or other type of substrate support. During operation, a substrate 108 is arranged on the ESC 106.

For example, the upper electrode 104 may comprise a gas distribution device 110 such as a showerhead that introduces and distributes process gases into the processing chamber 102. The showerhead 110 may comprise a stem portion comprising one end connected to a top surface of the processing chamber 102. A base portion of the showerhead 110 is generally cylindrical and extends radially outwardly from an opposite end of the stem portion at a location that is spaced from the top surface of the processing chamber 102. A substrate-facing surface or faceplate of the base portion of the showerhead 110 comprises a plurality of outlets or features (e.g., slots or through holes) through which vaporized precursor, process gas, cleaning gas, or purge gas flows into the processing chamber 102.

The ESC 106 can be manufactured according to the present disclosure as shown and described below in further detail with reference to FIGS. 2-8. Briefly, the ESC 106 comprises a baseplate 112 that acts as a lower electrode. The baseplate 112 comprises a metallic material (e.g., aluminum or an alloy). A ceramic plate 114 is arranged on a top surface of the baseplate 112. A thermal resistance layer (also called a bond layer) 116 is arranged between the ceramic plate 114 and the baseplate 112 to bond the ceramic plate 114 to the baseplate 112 as described below in detail with reference to FIGS. 2-8. The ceramic plate 114 comprises a heater array 152 according to the present disclosure to heat the substrate 108. The heater array 152 comprises printed resistive traces embedded in the ceramic plate 114. One or more additional heaters called zone heaters or primary heaters (not shown) may be arranged above or below the heater array 152. Additionally, while not shown, one or more temperature sensors may be disposed in the ceramic plate 114.

The baseplate 112 further comprises a cooling system to cool the ESC 106 and

to control the temperature of the substrate 108. The cooling system uses a fluid (e.g., a gas such as helium) supplied by a fluid delivery system 154 to cool the ESC 106 and to control the temperature of the substrate 108. For example, the cooling system comprises cooling channels 118 through which the fluid from the fluid delivery system 154 is flowed to cool the ESC 106 and to control the temperature of the substrate 108.

If plasma is used, an RF generating system (or an RF source) 120 generates and outputs an RF voltage to one of the upper electrode 104 and the lower electrode (e.g., the baseplate 112 of the ESC 106). The other one of the upper electrode 104 and the baseplate 112 may be DC grounded, AC grounded, or floating. For example, the RF generating system 120 may comprise an RF generator 122 that generates RF power that is fed by a matching and distribution network 124 to the upper electrode 104 or the baseplate 112. In other examples, while not shown, the plasma may be generated inductively or remotely and then supplied to the processing chamber 102.

A gas delivery system 130 comprises one or more gas sources 132-1, 132-2, . . . , and 132-N (collectively gas sources 132), where N is an integer greater than zero. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. A vapor delivery system 142 supplies vaporized precursor to the manifold 140 or another manifold (not shown) that is connected to the processing chamber 102. An output of the manifold 140 is fed to the processing chamber 102. The gas sources 132 may supply process gases, cleaning gases, or purge gases.

A temperature controller 150 may be connected to the heater array 152, the zone heaters, and the temperature sensors in the ceramic plate 114. The temperature controller 150 may be used to control the heater array 152 and the zone heaters to control a temperature of the ESC 106 and the substrate 108. The temperature controller 150 may communicate with the fluid delivery system 154 to control fluid flow through the cooling system 118 to cool the ESC 106. A valve 156 and pump 158 may be used to evacuate reactants from the processing chamber 102. A system controller 160 controls the components of the substrate processing system 100.

FIG. 2 shows a simplified cross-sectional view of components of an ESC 200 according to the present disclosure. The components of the ESC 200 are shown separated from each other to illustrate the assembly and manufacturing method described below. Further, only those components that concern the present disclosure are simplistically shown.

For example, the ESC 200 comprises a baseplate 202 and a ceramic plate 204. The ESC 200 may be similar to the ESCs 30 and 106 described above with reference to FIGS. 1A and 1B and may be used in the substrate processing systems 10 and 100 described above with reference to FIGS. 1A and 1B. After the ESC 200 is manufactured as described below, a substrate 206 can be arranged on the ceramic plate 204 and processed as described above with reference to FIGS. 1A and 1B.

The baseplate 202 comprises a gas inlet 210 through which a gas (e.g., helium) is supplied. The baseplate 202 comprises a plenum 212 defined by a top surface 214, a bottom surface 216, and a sidewall 218 of the baseplate 202. The plenum 212 is shown simplistically. The baseplate 202 may instead comprise fluid flow channels similar to the cooling channels 38 and 118 shown and described above with reference to FIGS. 1A and 1B. Hereinafter, the fluid flow channels are called the plenum 212. The gas inlet 210 is in fluid communication with the plenum 212.

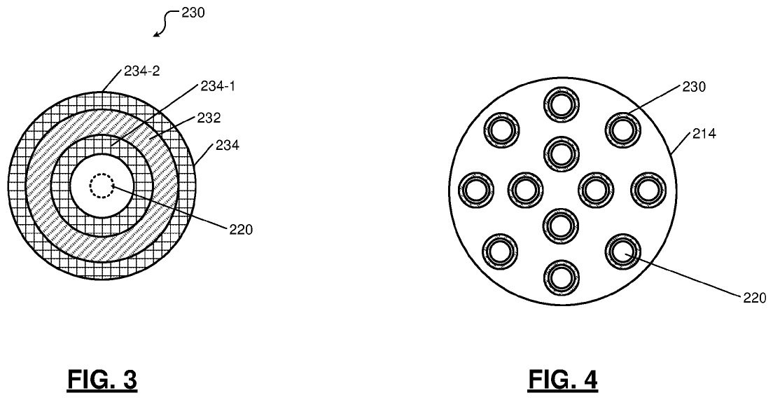

The baseplate 202 comprises a plurality of through holes 220-1, 220-2, 220-3, and 220-4 (collectively the through holes 220). While only four through holes 220 are shown for illustrative purposes, the baseplate 202 may comprise multiple through holes 220. The through holes 220 may be arranged in a pattern (e.g., zones). An example of the pattern is shown in FIG. 4. The through holes 220 extend from the top surface 214 of the baseplate 202 into the plenum 212. The through holes 220, the plenum 212, and the gas inlet 210 are in fluid communication with each other.

The ceramic plate 204 also comprises a plurality of through holes 222-1, 222-2, 222-3, and 222-4 (collectively the through holes 222). Again, while only four through holes 220 are shown for illustrative purposes, the ceramic plate 204 may comprise multiple through holes 220. The through holes 222 extend from a top surface 224 of the ceramic plate 204 to a bottom surface 226 of the ceramic plate 204. The through holes 222 are arranged in the same pattern as the through holes 220. Accordingly, when the ceramic plate 204 is bonded to the baseplate 202 as described below, the through holes 222 are aligned with the through holes 220 (see FIG. 5).

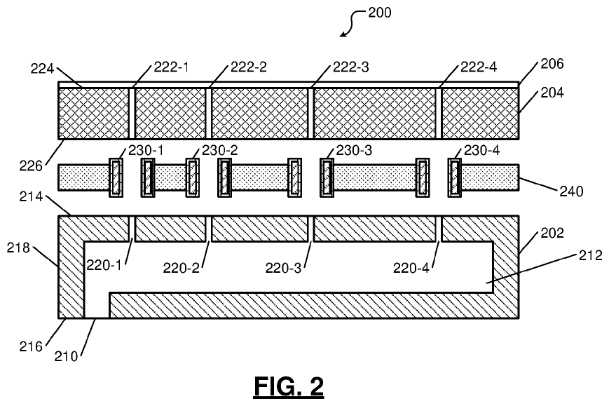

During manufacturing of the ESC 200, the ceramic plate 204 is bonded to the baseplate 202 by forming a bond layer (shown in FIG. 5) between the ceramic plate 204 and the baseplate 202. The bond layer is formed as follows. Before forming the bond layer, a plurality of washers 230-1, 230-2, 230-3, and 230-4 (collectively the washers 230) are disposed on the top surface 214 of the baseplate 202 around the through holes 220. A plan view of the washers 230 arranged on the top surface 214 of the baseplate 202 is shown and described in further detail with reference to FIG. 4. The washers 230 comprise a core 232 encapsulated in a coating 234. The washers 230 are described in further detail with reference to FIG. 3.

After arranging the washers 230 on the baseplate 202, a layer 240 of uncured liquid silicone is disposed on the top surface 214 of the baseplate 202. The washers 230 are taller than the thickness (i.e., height) of the layer 240 of uncured liquid silicone. Accordingly, the washers 230 prevent the uncured liquid silicone from flowing into the through holes 220 during the manufacture of the ESC 200. After disposing the layer 240 of uncured liquid silicone, the ceramic plate 204 and the baseplate 202 are compressed together while the layer 240 of uncured liquid silicone is cured. When the layer 240 of uncured liquid silicone is cured, the bond layer (shown in FIG. 5) is formed between the ceramic plate 204 and the baseplate 202. The bond layer bonds the ceramic plate 204 and the baseplate 202.

During the formation of the bond layer (i.e., during curing and compression), the washers 230 compress. After the curing and compression, inner diameters of the washers 230 align with the diameters of the through holes 220 and 222 (see FIG. 5). Accordingly, after the formation of the bond layer (i.e., after the ESC 200 is manufactured as described above), the gas inlet 210, the plenum 212, and the through holes 220 and 222 are in fluid communication with each other (see FIG. 5). In use, the substrate 206 can be arranged on the ceramic plate 204 during processing. The gas supplied through the inlet 210 flows via the plenum 212 and the through holes 220 and 222 and is used to control the temperature of the substrate 206 during processing.

FIG. 3 shows a transverse section of the washer 230 before the formation (i.e., before curing and compression) of the bond layer in further detail. The washer 230 is annular. The washer 230 comprises the core 232 and the coating 234 disposed around the core 232. The core 232 is annular. The core 232 is encapsulated (i.e., coated) with the coating 234. The coating 234 is disposed around inner and outer diameters of the core 232. The core 232 may be fully or partially coated with the coating 234. For example, when the washer 230 is manufactured, the coating 234 may be patterned on the inner and outer diameters of the core 232.

The coating 234 comprises a first (inner) layer 234-1 disposed on the inner diameter (ID) of the core 232 and a second (outer) layer 234-2 disposed on the outer diameter (OD) of the core 232. The first and second layers 234-1 and 234-2 are annular. The core 232 and the first and second layers 234-1 and 234-2 are coaxial. The OD of the first layer 234-1 matches the ID of the core 232. The ID of the second layer 234-2 matches the OD of the core 232. The ID of the first layer 234-1 is the ID of the washer 230. The OD of the second layer 234-2 is the OD of the washer 230. The ID of the washer 230 (i.e., the ID of the first layer 234-1) is greater than the diameter of the through hole 220 before the bond layer is cured (see FIG. 4). The ID of the washer 230 (i.e., the ID of the first layer 234-1) is almost equal to and matches the diameter of the through hole 220 after the bond layer is cured (see FIG. 5).

A thickness of the washer 230 is a sum the thickness of the core 232 and a thickness of the coating 234. The thickness of the coating 234 is a sum of thicknesses of the first and second layers 234-1 and 234-2. The thickness of the washer 230 is a distance between the ID of the washer 230 and the OD of the washer 230. That is, the thickness of the washer 230 is the distance between the ID of the first layer 234-1 and the OD of the second layer 234-2.

The core 232 comprises 30-90% of the thickness of the washer 230. The coating 234 (i.e., the first and second layers 234-1 and 234-2 combined) comprises 70-10% of the thickness of the washer 230. For example, when the thickness of the core 232 is 40% of the thickness of the washer 230, the thickness of the coating 234 is 60% of the thickness of the washer 230. When the thickness of the core 232 is 50% of the thickness of the washer 230, the thickness of the coating 234 is 50% of the thickness of the washer 230. When the thickness of the core 232 is 60% of the thickness of the washer 230, the thickness of the coating 234 is 40% of the thickness of the washer 230; and so on.

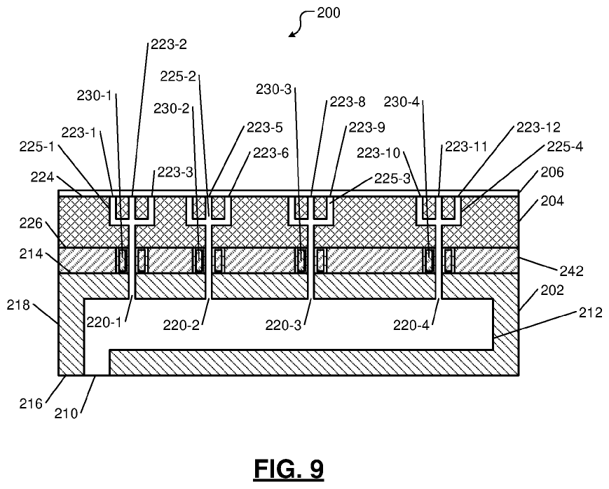

In some examples, the thickness of the coating 234 (i.e., the sum of thicknesses of the first and second layers 234-1 and 234-2) is less than or equal to the thickness of the core 232. In some examples, the thicknesses of the first and second layers 234-1 and 234-2 can be different, and the sum of the thicknesses of the first and second layers 234-1 and 234-2 can be less than or equal to the thickness of the core 232. Conversely, in other examples, the thickness of the coating 234 (i.e., the sum of thicknesses of the first and second layers 234-1 and 234-2) is greater than or equal to the thickness of the core 232. In some examples, the thicknesses of the first and second layers 234-1 and 234-2 can be different, and the sum of the thicknesses of the first and second layers 234-1 and 234-2 is greater than or equal to the thickness of the core 232. The core 232 and the first and second layers 234-1 and 234-2 with specific thicknesses described above can be manufactured using multi-sheet lamination or other manufacturing processes. Examples of dimensions of the washer 230 are provided below after the description of FIG. 8.

The core 232 comprises a cured elastic material (e.g., silicone, urethane, or flexible epoxy). The core 232 provides a consistent reactive force between the ceramic plate 204 and the baseplate 202 during the use of the ESC 200. The coating 234 comprises a polymeric material. For example, the polymeric material comprises polytetrafluoroethylene (PTFE) or perfluoroalkoxy alkanes (PFA). The polymeric material has a high melt strength, stability at high processing temperatures, excellent crack and stress resistance, and a low coefficient of friction. As a result, the polymeric material can withstand hostile environments involving electrical, chemical, and thermal harshness and mechanical stress such as those experienced by the ESC 200 in a processing chamber. The coating 234 provides a high-quality, enduring chemical seal during the use of the ESC 200, which prevents the through holes 220 and 222 from clogging.

Specifically, the core 232 has mechanical properties to withstand the compressive forces between the baseplate 202 and the ceramic plate 204 during the manufacture and use of the ESC 200. Additionally, the core 232 has thermodynamic properties to withstand the curing of the bond layer and high process temperatures experienced by the ESC 200 during use in the processing chambers.

Furthermore, the coating 234 does not erode due to due to high process temperatures, temperature cycling, and exposure to reactive plasma species occurring during the use of the ESC 200 in the processing chambers. The coating 234 acts as a diffusive barrier to plasma or other reactive species used in the processing chambers. The coating 234 also acts as a diffusive barrier to plasticizers and/or uncured material in the core 232 that can otherwise (i.e., in the absence of the coating 234) clog the through holes 220 and 222. As a result, not only the through holes 220 and 222 remain unclogged, but the bonding between the ceramic plate 204 and the baseplate 202 is also not impaired after several thousand hours of use of the ESC 200 in the processing chambers.

More specifically, due to the coating 234, degraded material and uncured plasticizers from the washers 230 do not leak into the through holes 220 and 222 and do not clog the holes 220 and 222. Further, uncured plasticizers from surrounding bonding material in the bond layer do not diffuse through the washers 230 and do not leak into the through holes 220 and 222, which prevents clogging of the through holes 220 and 222. Furthermore, the coating 234 also prevents clogging of the through holes 220 and 222 due to low gas flow during wafer-less auto-clean (WAC), which can result in arcing, light-up, and ultimately bond erosion and degradation of the bond layer, which can clog the through holes 220 and 222 in the absence of the coating 234. By preventing clogging of the through holes 220 and 222, the flow of the gas via the through holes 220 and 222 used to regulate the temperature of the substrate 206 during processing is not hindered. Further, by using the washers 230, the bonding between the ceramic plate 204 and the baseplate 202 is not impaired, which prevents failure of the ESC 200.

FIG. 4 shows a plan view of through holes 220 and the washers 230 arranged around the through holes 220 on the baseplate 202 during the manufacture of the ESC 200 before the bond layer is cured. For example, the through holes 220 can be arranged on the top surface 214 of the baseplate 202 in a pattern as shown. Alternatively, the through holes 220 may be arranged in any other pattern that is suitable for controlling the temperature of the substrate 206 using the gas supplied through the inlet 210. For example, the pattern may comprise concentric zones, quadrants (e.g., pie shaped zones), or any other pattern. The pattern in which the through holes 220 are arranged can be selected depending on process requirements. The through holes 222 in the ceramic plate 204 are arranged in the same pattern as the through holes 220. Accordingly, the washers 230 are also arranged in the same pattern as the through holes 220 and 222.

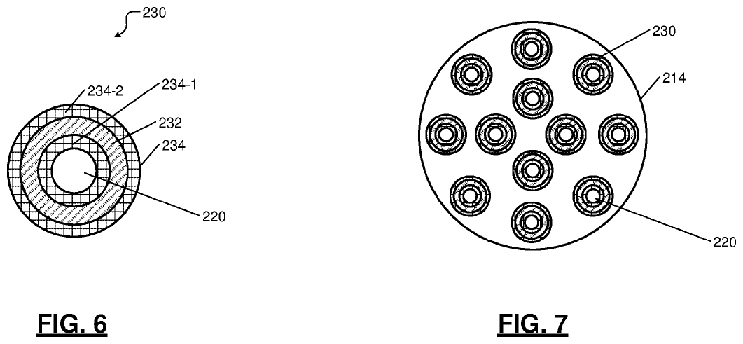

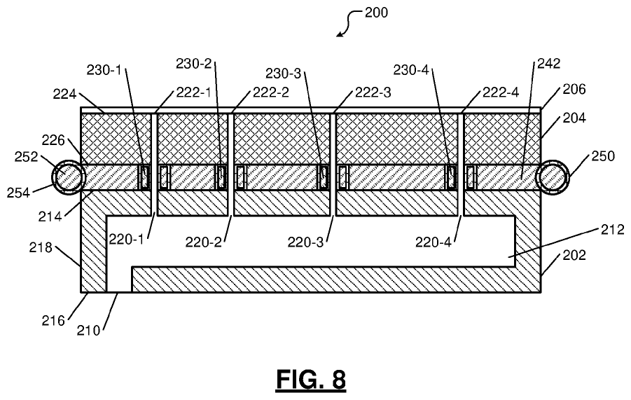

FIG. 5 shows a cross-sectional view of the ESC 200 manufactured (i.e., after curing and compression) as described above with reference to FIGS. 2-4. In the ESC 200, a bond layer 242 is formed between the ceramic plate 204 and the baseplate 202 when the layer 240 shown in FIG. 1 is cured and the ceramic plate 204 and the baseplate 202 are compressed as described above. The bond layer 242 bonds the ceramic plate 204 and the baseplate 202. As shown in FIGS. 6 and 7 in further detail, the IDs of the washers 230 in the bond layer 242 align with the through holes 220 and 222 after the layer 240 is cured and the ceramic plate 204 and the baseplate 202 are compressed. Specifically, after the layer 240 is cured and the ceramic plate 204 and the baseplate 202 are compressed, the IDs of the first layers 234-1 of the washers 230 align with the diameters of the through holes 220 and 222. The washers 230 prevent the through holes 220 and 222 from clogging as described above.

FIG. 6 shows a transverse section of the washer 230 after the formation (i.e., after curing and compression) of the bond layer 242 in further detail. When the bond layer 242 is formed after the curing and compression processes are performed as described above, the ID of the washer 230 aligns with the diameter of the through hole 220. Specifically, the ID of the first layer 234-1 of the washer 230 aligns with the diameter of the through hole 220. The ID of the first layer 234-1 of the washer 230 also aligns with the diameter of the corresponding through hole 222 in the ceramic plate 204 as shown in FIGS. 5 and 8.

FIG. 7 shows a plan view of the through holes 220 and the washers 230 around the through holes 220 on the baseplate 202 after the formation (i.e., after curing and compression) of the bond layer 242. Again, when the bond layer 242 is formed after the curing and compression processes are performed as described above, the IDs of the washers 230 in the bond layer 242 align with the diameters of the through holes 220. Specifically, the IDs of the first layers 234-1 of the washers 230 align with the diameters of the through holes 220. The IDs of the first layers 234-1 of the washers 230 also align with the diameters of the through holes 222 in the ceramic plate 204 as shown in FIGS. 5 and 8.

FIG. 8 shows a cross-sectional view of the ESC 200 manufactured as described above with reference to FIGS. 2-4 with the addition of an O-ring 250 disposed around the bond layer 242. The O-ring 250 protects the outer edges of the bond layer 242. Specifically, the O-ring 250 prevents the process gases and other reactive species from reacting with the bond layer 242. The O-ring 250 comprises a core 252 and a coating 254. The core 252 of the O-ring 250 comprises a similar material as the core 232 of the washers 230. The core 252 of the O-ring 250 is therefore not described again in detail for brevity. The coating 254 of the O-ring 250 comprises a similar material as the coating 234 of the washers 230. The coating 254 of the O-ring 250 is therefore not described again in detail for brevity.

The O-ring 250 differs from the washers 230 structurally and functionally in many respects. Specifically, the O-ring 250 is significantly different in dimensions and serves different functions than the washers 230. For example, the O-ring 250 differs structurally from the washers 230 in that the O-ring 250 has a circumference (ID) of about 300 mm (about the diameter of the ESC 200) whereas the washers 230 have a circumference (i.e., the OD of the second layer 234-2) of about 2-20 mm. Further, the O-ring 250 has a cross-sectional diameter of about 100-150 mils whereas the washers 230 have a cross-sectional diameter (i.e., thickness) of about 2-10 mils.

Functionally, the O-ring 250 protects the outer edges of the bond layer 240 whereas the washers 230 prevent the through holes 220 and 220 from clogging. Further, unlike the washers 230, the O-ring 250 does not experience and therefore does not have to endure the curing and bonding process used to bond the ceramic plate 204 and the baseplate 202. Furthermore, the O-ring 250 does not experience and therefore does not have to withstand the mechanical stress and the arcing and the light-up experienced by the washers 230. Moreover, while the O-ring 250 can be replaced, the washers 230 cannot be replaced.

Accordingly, there are vast structural disparities between the O-ring 250 and the washers 230. Further, there are significant differences between the harshness and stress experienced by the O-ring 250 and the washers 230. Furthermore, the O-ring 250 and the washers 230 perform different functions. As such, the O-ring 250 and the washers 230 are structurally and functionally dissimilar and cannot be compared with each other.

Furthermore, the washers 230 are designed to perform the specific functions described above during both the manufacture and use of the ESC 200. Accordingly, while use of washers may be prevalent in other technical fields, the washers 230 are specifically designed withstand the harsh electrical, chemical, and thermal environment and mechanical stress that are specific to the ESC 200.

For example, the ESC 200 is subjected to voltages on the order of several thousand volts during plasma generation. The ESC 200 is heated to temperatures of several hundred degrees, cooled, and reheated during substrate processing. Thus, the washers 230 in the ESC 200 are subjected to extreme temperatures and thermal cycling. Further, reactive species of highly corrosive process gases tend to flow via the through holes 220 and 222 exposing the coating 234 of the first layers 234-1 of the washers 230 to the harsh chemistries of the process gases. Furthermore, the coating 234 of the first layers 234-1 of the washers 230 is also subjected to arcing and light-up (i.e., plasma generated within the through holes 220 and 222) as described above. The washers 230 are designed to withstand and endure these extremely harsh environments that are specific to the ESC 200 over a period of several thousand hours. The washers 230 withstand and endure these harsh environments despite their miniature size. Notably, the washers 230 are designed to survive these harsh environments after already being subjected to the thermal and mechanical stresses during the bonding of the ceramic plate 204 and the baseplate 202. Accordingly, the washers 230 are unlike other washers that may be used in other environments in other technical fields.

In the examples shown in FIGS. 2-8, the ceramic plate 204 has been shown and described as comprising orthogonal through holes 222. However, the present disclosure is not limited to the ceramic plate 204 comprising orthogonal through holes 222. In some examples, the ceramic plate 204 may comprise more complex gas distribution plenums or channels rather than orthogonal through holes 222. For example, as shown as described below with reference to FIGS. 9 and 10, a plurality of holes in the ceramic plate 204 may be connected to a single through hole 220 in the baseplate 202 using one of the channels in the ceramic plate 204. The holes in the ceramic plate 204 may have different diameters. The holes in the ceramic plate 204 may extend through the ceramic plate 204 at various angles. The holes and channels can be disposed in the ceramic plate 204 using various other arrangements of which two examples are shown and described below with reference to FIGS. 9 and 10.

FIGS. 9 and 10 show examples of a ceramic plate comprising plenums instead of orthogonal through holes. Elements that have been shown and described above with reference to FIGS. 2-8 are not described again for brevity. Further, while not shown, the O-ring 250 may be additionally disposed around the bond layer 242 in FIGS. 9 and 10.

In FIGS. 9 and 10, the ceramic plate 204 comprises a plurality of plenums or channels (hereinafter channels) 225-1, 225-2, 225-3, and 225-5 (collectively the channels 225). The channels 225 are passages bored through the ceramic plate 204 between the top surface 224 of the ceramic plate 204 and the bottom surface 226 of the ceramic plate 204. While only four channels 225 are shown for illustrative purposes, the ceramic plate 204 may comprise fewer or more than four channels 225. At the bottom surface 226 of the ceramic plate 204, each channel 225 has an opening (hole) that mates with a through hole 220 of the baseplate 202. At the top surface 224 of the ceramic plate 204, each channel 225 comprises a plurality openings (holes) 223-1, 223-2, . . . , and 223-12 (collectively the holes 223). Accordingly, each channel 225 connects an opening (hole) at the bottom surface 226 of the ceramic plate 204 to two or more openings (holes) 223 at the top surface 224 of the ceramic plate 204.

The channels 225 need not be right-angled as shown in FIG. 9. Instead, the channels 225 may extend non-orthogonally as shown in FIG. 10. Further, the channels 225 and the holes 223 can have equal or unequal diameters. Furthermore, while not shown, one or more channels 225 may be interconnected. For example, the channel 225-1 may be connected to the channel 225-2, and the channel 225-3 may be connected to the channel 225-4. The through holes 222 of the ceramic plate 204 shown in FIGS. 2-8 and the through holes 223 and the channels 225 of the ceramic plate 204 shown in FIGS. 9 and 10 can be collectively called passages.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may comprise chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g., a server) can provide process recipes to a system over a network, which may comprise a local network or the Internet. The remote computer may comprise a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. An electrostatic chuck for a substrate processing system comprising:
a baseplate of the electrostatic chuck, the baseplate comprising a metallic material, a sidewall and upper and lower surfaces of the baseplate defining a plenum, the baseplate further comprising an inlet in fluid communication with the plenum and a first plurality of through holes extending from the upper surface to the plenum;
a ceramic plate of the electrostatic chuck, the ceramic plate comprising a second plurality of through holes extending between upper and lower surfaces of the ceramic plate; and
a bond layer that bonds the baseplate and the ceramic plate, the bond layer comprising a plurality washers, each washer comprising:
a core comprising a third material; and
a coating of a fourth material surrounding the core;
wherein the washers and the bond layer are of the same height; and
wherein inner diameters of the washers are aligned with diameters of the first and second plurality of through holes.

2. The electrostatic chuck of claim 1 wherein the core and the coating are annular and coaxial.

3. The electrostatic chuck of claim 1 wherein the inlet, the plenum, the inner diameters of the washers, and the first and second plurality of through holes are in fluid communication with each other.

4. The electrostatic chuck of claim 1 wherein the bond layer comprises the third material.

5. The electrostatic chuck of claim 1 wherein the third material comprises silicone, urethane, or flexible epoxy.

6. The electrostatic chuck of claim 1 wherein the fourth material comprises polytetrafluoroethylene (PTFE) or perfluoroalkoxy alkanes (PFA).

7. The electrostatic chuck of claim 1 wherein the coating comprises a first layer of the fourth material disposed on an inner diameter of the core and a second layer of the fourth material disposed on an outer diameter of the core.

8. The electrostatic chuck of claim 7 wherein a sum of thicknesses of the first and second layers is less than or equal to a thickness of the core.

9. The electrostatic chuck of claim 7 wherein a sum of thicknesses of the first and second layers is greater than or equal to a thickness of the core.

10. The electrostatic chuck of claim 7 wherein thicknesses of the first and second layers are different.

11. The electrostatic chuck of claim 1 wherein a diameter of the washers is 2-20 mm.

12. The electrostatic chuck of claim 1 wherein a thickness of the washers is 2-10 mils.

13. The electrostatic chuck of claim 1 wherein:
the core comprises 30-90% of a thickness of the washer; and
the coating comprises 70-10% of the thickness of the washer.

14. The electrostatic chuck of claim 1 further comprising an O-ring arranged around the bond layer wherein the O-ring comprises:
a second core comprising the third material; and
a second coating comprising the fourth material surrounding the second core.

15. The electrostatic chuck of claim 14 wherein:
an inner diameter of the O-ring is 300 mm; and
a cross-sectional diameter of the O-ring is 100-150 mils.

16. The electrostatic chuck of claim 1 wherein the ceramic plate comprises one or more passages and wherein one of the passages connects one of the second plurality of through holes at the lower surface of the ceramic plate to at least two of the second plurality of through holes at the upper surface of the ceramic plate.

17. An electrostatic chuck for a substrate processing system comprising:
a baseplate comprising a sidewall and upper and lower surfaces of the baseplate defining a plenum, an inlet in fluid communication with the plenum, and a first plurality of through holes extending from the upper surface to the plenum;
a ceramic plate comprising a second plurality of through holes extending through the ceramic plate; and
a bond layer bonding the baseplate and the ceramic plate, the bond layer comprising a plurality washers, each washer comprising a core and a coating disposed on the core,
wherein inner diameters of the washers are aligned with diameters of the first and second plurality of through holes.

18. The electrostatic chuck of claim 17 wherein the core and the coating are annular and coaxial.

19. The electrostatic chuck of claim 17 wherein:
the baseplate comprises a metallic material;
the bond layer and the core comprise a third material; and
the coating comprises a polymeric material.

20. The electrostatic chuck of claim 17 wherein:
the baseplate comprises a metallic material;
the bond layer comprises silicone;
the core comprises silicone, urethane, or flexible epoxy; and
the coating comprises polytetrafluoroethylene (PTFE) or perfluoroalkoxy alkanes (PFA).

21. The electrostatic chuck of claim 17 wherein the washers and the bond layer are of the same height.

22. The electrostatic chuck of claim 17 wherein the coating partially surrounds of the core.

23. The electrostatic chuck of claim 17 wherein the coating fully surrounds of the core.

24. The electrostatic chuck of claim 17 wherein the inlet, the plenum, the inner diameters of the washers, and the first and second plurality of through holes are in fluid communication with each other.

25. The electrostatic chuck of claim 17 wherein the coating comprises a first layer disposed on an inner diameter of the core and a second layer disposed on an outer diameter of the core.

26. The electrostatic chuck of claim 25 wherein a sum of thicknesses of the first and second layers is less than or equal to a thickness of the core.

27. The electrostatic chuck of claim 25 wherein a sum of thicknesses of the first and second layers is greater than or equal to a thickness of the core.

28. The electrostatic chuck of claim 25 wherein thicknesses of the first and second layers are different.

29. The electrostatic chuck of claim 17 wherein a diameter of the washers is 2-20 mm.

30. The electrostatic chuck of claim 17 wherein a thickness of the washers is 2-10 mils.

31. The electrostatic chuck of claim 17 wherein:
the core comprises 30-90% of a thickness of the washer; and
the coating comprises 70-10% of the thickness of the washer.

32. The electrostatic chuck of claim 17 further comprising an O-ring arranged around the bond layer wherein the O-ring comprises:
a second core comprising the same material as the core of the washers; and
a second coating surrounding the second core and comprising the same material as the coating of the washers.

33. The electrostatic chuck of claim 32 wherein:
an inner diameter of the O-ring is 300 mm; and
a cross-sectional diameter of the O-ring is 100-150 mils.

34. The electrostatic chuck of claim 17 wherein the ceramic plate comprises one or more passages and wherein one of the passages connects one of the second plurality of through holes at the lower surface of the ceramic plate to at least two of the second plurality of through holes at the upper surface of the ceramic plate.
